(19) United States
(12) Patent Application Publication
(10) Pub. No.: US 2015/0022327 A1
(43) Pub. Date: Jan. 22, 2015

(54) Externally triggered memory type liquid crystal thin film

(71) Applicant: Chung Hua University, Hsinchu (TW)

(72) Inventors: Chien-Hung Wu, Hsinchu (TW); Li Fu Teng, Hsinchu (TW); Shui Jinn Wang, Hsinchu (TW); Kow Ming Chang, Hsinchu (TW)

(73) Assignee: Chung Hua University, Hsinchu (TW)

(21) Appl. No.: 14/203,525

(22) Filed: Mar. 10, 2014

(30) Foreign Application Priority Data
Jul. 18, 2013 (TW) 102213557

(51) Int. Cl. G06K 7/00; G11C 13/04

(52) U.S. Cl. CPC G06K 7/0008; G11C 13/048
USPC 340/10.34; 365/108

(57) ABSTRACT

An externally triggered memory type liquid crystal thin film is provided with a wireless communication module including first and second driver units wherein a current is generated in the second driver unit when a distance between the first driver unit and the second driver unit is equal to or less than a predetermined value; and a light adjustment module including a first conduction layer electrically connected to a first terminal of the second driver unit so that the second driver unit supplies the current to the first conduction layer, a second conduction layer electrically connected to a second terminal of the second driver unit, and a liquid crystal layer formed between the first and second conduction layers so that an electric field is generated in the liquid crystal layer by both the first and second conduction layers.

### BACKGROUND OF THE INVENTION

1. Field of the Invention

The invention relates to memory type liquid crystal thin film and more particularly to an externally triggered memory type liquid crystal thin film triggered by using radio frequency.

2. Description of Related Art

As the technologies advance in recent years, memory type liquid crystal thin films are developed. The memory type liquid crystal thin film can be activated without external power. Power is required to supply to the memory type liquid crystal thin film only when a state of change is shown. Further, the changed state can be maintained after removing the power. It is an energy saving device. Thus, the memory type liquid crystal thin films are gaining popularity in applications including advertisement displays and e-books with long time information showing being desired.

However, while the typical memory type liquid crystal thin films have energy saving feature, external power or batteries are still required to connect to them in order to receive state change instructions. It is understood that energy consumption is inevitable if there is an electrical connection between a power source and an electrical/electronic device irrespective of the electrical/electronic device being used or in a ready to use state.

Therefore, there is a need of providing an externally triggered memory type liquid crystal thin film triggered by using radio frequency so as to eliminate the connection to an external power source or batteries, save energy, and bring convenience to users.

### SUMMARY OF THE INVENTION

It is therefore one object of the invention to provide an externally triggered memory type liquid crystal thin film is provided with a wireless communication module including a first driver unit and a second driver unit wherein a current is generated in the second driver unit when a distance between the first driver unit and the second driver unit is equal to or less than a predetermined value; and a light adjustment module including a first conduction layer electrically connected to a first terminal of the second driver unit so that the second driver unit supplies the current to the first conduction layer, a second conduction layer electrically connected to a second terminal of the second driver unit, and a liquid crystal layer formed between the first and second conduction layers so that an electric field is generated in the liquid crystal layer by both the first and second conduction layers.

In comparison with the typical memory type liquid crystal thin film, the externally triggered memory type liquid crystal thin film of the invention can generate an induction current in the wireless communication module and the current is supplied to the light adjustment module. In brief, external power source or battery is not required to connect to the second driver unit in order to activate the memory type liquid crystal thin film. Therefore, the externally triggered memory type liquid crystal thin film of the invention can save energy and is effective.

### BRIEF DESCRIPTION OF THE DRAWINGS

The invention, as well as its many advantages, may be further understood by the following detailed description and drawings in which:

FIG. 1 is a block diagram of an externally triggered memory type liquid crystal thin film in accordance with the invention.

### DETAILED DESCRIPTION OF THE INVENTION

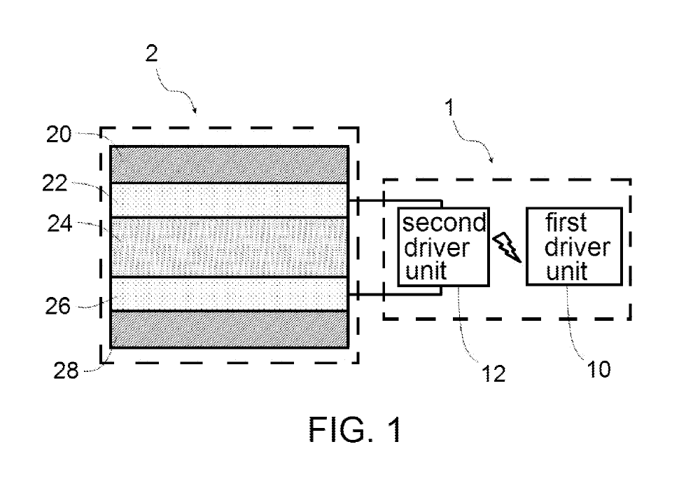

Referring to FIG. 1, an externally triggered memory type liquid crystal thin film in accordance with the invention comprises a wireless communication module 1 and a light adjustment module 2 as discussed in detail below.

The wireless communication module 1 comprises a first driver unit 10 and a second driver unit 12. Radio Frequency Identification (RFID) is used to transfer data from the first driver unit 10 to the second driver unit 12.

Essentially, an RFID reader and an RFID tag are provided in an RFID device. An inductor loop is provided in each of the RFID reader and the RFID tag. An electromagnetic induction is generated in the RFID tag when a distance between the inductor loops of the RFID reader and the RFID tag is sufficiently small (e.g., less or equal to a predetermined value) by moving the RFID reader toward the RFID tag. And in turn, an induction current is generated in the RFID tag. That is, no external power is required to connect to the RFID system.

In the invention, the wireless communication module 1 is an RFID device, the first driver unit 10 is an RFID reader, and the second driver unit 12 is an RFID tag. An induction current is generated in the second driver unit 12 when a distance between the first driver unit 10 and the second driver unit 12 is less or equal to a predetermined value by moving the first driver unit 10 toward the second driver unit 12.

The light adjustment module 2 is a liquid crystal thin film and comprises, from top to bottom, a first substrate 20, a first conduction layer 22, a liquid crystal layer 24, a second conduction layer 26, and a second substrate 28.

The first conduction layer 22 is provided on a bottom of the first substrate 20 and electrically connected to a first terminal of the second driver unit 12 so that the second driver unit 12 may supply current to the first conduction layer 22. The liquid crystal layer 24 is provided on a bottom of the first conduction layer 22 opposite to the first substrate 20. The second conduction layer 26 is provided on a bottom of the liquid crystal layer 24 and electrically connected to a second terminal of the second driver unit 12 so that an electric field is created in the liquid crystal layer 24 by both the first and second conduction layers 22, 26. The second substrate 28 is provided on a bottom of the second conduction layer 26 opposite to the liquid crystal layer 24. Specifically, the light adjustment module 2 is a memory type liquid crystal thin film. The liquid crystal layer 24 is bi-stable Ferroelectric Liquid Crystal (FLC) having a plurality of liquid crystal molecules which are oriented in different directions in order to change between a bright state and a dark state. After each state change, its current state can be maintained to a next state even when a trigger source is removed. In the invention, for example, the liquid crystal layer 24 is in a bright state and a distance between the first driver unit 10 and the second driver unit 12 is less or equal to the predetermined value, then an induction current is generated in each of the first and second conduction layers 22, 26. That is, an electric field is generated in the liquid crystal layer 24 by the first and second conduction layers 22, 26. In response to triggering the liquid crystal layer 24 by the wireless communication module 1, the liquid crystal molecules of the liquid crystal layer 24 are oriented from the original direction to a desired direction due to the orientation effect of the electric field. As a result, the bright state of the liquid crystal layer 24 changes to a dark state.

Subsequently, in response to the distance between the first driver unit 10 and the second driver unit 12 is less or equal to the predetermined value, an electric field is generated in the liquid crystal layer 24 by the first and second conduction layers 22, 26, the liquid crystal layer 24 is triggered by the wireless communication module 1, the liquid crystal molecules of the liquid crystal layer 24 are oriented from the original direction to a desired direction due to the orientation effect of the electric field. As a result, the dark state of the liquid crystal layer 24 changes to a bright state.

Alternatively, each of the first and second substrates 20, 28 are a flexible transparent substrate, and each of the first and second conduction layers 22, 26 are a transparent electrode.

In comparison with the typical memory type liquid crystal thin film, the externally triggered memory type liquid crystal thin film of the invention can generate an induction current in the wireless communication module and the current is supplied to the light adjustment module. In brief, external power source or battery is not required to connect to the second driver unit in order to activate the memory type liquid crystal thin film. Therefore, the externally triggered memory type liquid crystal thin film of the invention can save energy and is effective.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. An externally triggered memory type liquid crystal thin film comprising:
a wireless communication module including a first driver unit and a second driver unit wherein a current is generated in the second driver unit when a distance between the first driver unit and the second driver unit is equal to or less than a predetermined value; and
a light adjustment module including a first conduction layer electrically connected to a first terminal of the second driver unit so that the second driver unit supplies the current to the first conduction layer, a second conduction layer electrically connected to a second terminal of the second driver unit, and a liquid crystal layer formed between the first and second conduction layers so that an electric field is generated in the liquid crystal layer by both the first and second conduction layers.

2. The externally triggered memory type liquid crystal thin film of claim 1, wherein the light adjustment module further comprises a first substrate on the first conduction layer opposite to the liquid crystal layer, and a second substrate on the second conduction layer opposite to the liquid crystal layer.

3. The externally triggered memory type liquid crystal thin film of claim 2, wherein each of the first and second substrates are a flexible transparent substrate.

4. The externally triggered memory type liquid crystal thin film of claim 2, wherein each of the first and second conduction layers are a glass electrode.

5. The externally triggered memory type liquid crystal thin film of claim 1, wherein the wireless communication module is an RFID device.

6. The externally triggered memory type liquid crystal thin film of claim 5, wherein the first driver unit is an RFID reader and the second driver unit is an RFID tag.

7. The externally triggered memory type liquid crystal thin film of claim 1, wherein the light adjustment module is a memory type liquid crystal thin film.

8. The externally triggered memory type liquid crystal thin film of claim 1, wherein the liquid crystal layer is a Ferroelectric Liquid Crystal (FLC).

9. The externally triggered memory type liquid crystal thin film of claim 1, wherein each of the first and second conduction layers are a transparent electrode.
